(19) United States
(12) Patent Application Publication
(10) Pub. No.: US 2013/0199824 A1
(43) Pub. Date: Aug. 8, 2013

(54) MICROELECTRONICS DEVICE INCLUDING ANISOTROPIC CONDUCTIVE LAYER AND METHOD OF FORMING THE SAME

(71) Applicant: Jin-Suk LEE, Yongin-City (KR)

(72) Inventor: Jin-Suk LEE, Yongin-City (KR)

(21) Appl. No.: 13/712,018

(22) Filed: Dec. 12, 2012

(30) Foreign Application Priority Data
Feb. 8, 2012 (KR) 10-2012-0012882

(51) Int. Cl. H05K 1/02; H05K 3/10

(52) U.S. Cl. CPC H05K 1/0298; H05K 3/10
USPC 174/251; 174/250; 29/846

(57) ABSTRACT

A microelectronics device includes a first substrate, first electrodes disposed on the first substrate, an insulating layer covering the first electrodes, the insulating layer including openings on the first electrodes, and an anisotropic conductive film on the insulating layer, the anisotropic conductive film including conductive particles electrically connected to the first electrodes through the openings.

### CROSS-REFERENCE TO RELATED APPLICATION

This application claims priority from Korean Patent Application No. 10-2012-0012882 filed on Feb. 8, 2012 in the Korean Intellectual Property Office, the disclosure of which is incorporated herein by reference in its entirety.

### BACKGROUND

1. Field

Example embodiments relate to a microelectronics device and a method of forming the same, and more particularly, to a microelectronics device including an anisotropic conductive layer and a method of forming the same.

2. Description of the Related Art

An interconnecting method using an anisotropic conductive film (ACF) is widely used to electrically connect two substrates, each having a plurality of electrodes. The ACF includes a plurality of conductive particles dispersed in a matrix, e.g., the plurality of conductive particles is disposed between electrodes of the two substrates to be connected to each other and electrically connect the two substrates. The substrates connected by the ACF may be one or more of, e.g., a general printed circuit board (PCB), a flexible printed circuit (FPC), and an integrated circuit chip.

Some applications for transmitting and receiving a larger amount of data include numerous electrodes. In a case of a small sized application, the number of electrodes per unit area increases, thereby reducing a distance between the electrodes. If the distance between the electrodes is reduced, the conductive particles of the ACF may contact unwanted electrodes, thereby causing a short therebetween and interconnection failures.

### SUMMARY

Example embodiments provide a microelectronics device including an ACF, which can increase densities of electrodes by preventing a short between the electrodes.

Example embodiments also provide a method for forming a microelectronics device including an ACF, which can increase densities of electrodes by preventing a short between the electrodes.

According to an embodiment, there is provided a microelectronics device including a first substrate, first electrodes disposed on the first substrate, an insulating layer covering the first electrodes, the insulating layer including openings on the first electrodes, and an anisotropic conductive film on the insulating layer, the anisotropic conductive film including conductive particles electrically connected to the first electrodes through the openings.

The opening may include a sidewall having a shape corresponding to the conductive particle.

The opening may include a sidewall having a curved cross-section.

The sidewall of the opening may have an arc-shaped cross-section.

The first electrodes and the conductive particles may contact each other through the openings.

A width of a surface of the opening facing the first electrode may be equal to or less than a width of a surface of the opening facing the anisotropic conductive film.

The microelectronics device may further include a second substrate facing the first substrate, the anisotropic conductive film being disposed between the first and second substrates, and second electrodes on the second substrate, the second electrodes facing and overlapping the first electrodes, and the second electrodes and the conductive particles being electrically connected to each other.

A thickness of the insulating layer may be equal to or less than a minimum width of the conductive particle.

The conductive particles may be on the first electrodes, each of the first electrodes being electrically connected to a respective conductive particle disposed thereon.

Each first electrode may be electrically connected to the conductive particle thereon through the opening.

Each first electrode may completely overlap a respective opening, such that there are no openings between adjacent first electrodes.

The insulating layer may be a single layer overlapping simultaneously all the first electrodes.

The microelectronics device may further include a second substrate facing the first substrate with the anisotropic conductive film disposed between the first and second substrates, and a plurality of second electrodes on the second substrate, the second electrodes facing and overlapping the first electrodes, the second electrodes and the conductive particles being electrically connected to each other, and the conductive particles disposed on overlapping areas of the first electrodes and second electrodes being electrically connected to the second electrodes, respectively.

Each of the first electrodes may have a first region and a second region, the second region having a smaller width than the first region.

The plurality of second electrodes may overlap the first regions of the plurality of first electrodes.

A minimum distance between adjacent ones of the plurality of first electrodes may be a distance between the first region of one of the plurality of first electrodes and the second region of the first electrode adjacent to the one first electrode.

The plurality of second electrodes may be arranged in a plurality of rows, adjacent ones of the plurality of second electrodes being in different rows of the plurality of rows.

According to another embodiment, there is also provided a method of forming a microelectronics device, the method including forming first electrodes on a first substrate, forming an insulating layer covering the first electrodes, providing an anisotropic conductive film on the insulating layer, the anisotropic conductive film including conductive particles dispersed in a matrix, forming second electrodes on a second substrate, arranging the second substrate with the second electrodes on the anisotropic conductive film, such that the first electrodes and the second electrodes overlap each other, and compressing the first substrate and the second substrate, such that the first and second electrodes compress against each other with the anisotropic conductive film therebetween.

Compressing the first and second substrates may include forming openings in the insulating layer by the conductive particles, such that the conductive particles are electrically connected to the first electrodes.

The openings may be formed only in regions overlapping the first and second electrodes, such that regions between adjacent first electrodes or regions between adjacent second electrodes include no openings.

### BRIEF DESCRIPTION OF THE DRAWINGS

The above and other features and advantages of the example embodiments will become more apparent by describing in detail preferred embodiments thereof with reference to the attached drawings, in which:

FIG. 1 is a cross-sectional view of a microelectronics device according to an embodiment;

FIG. 2 is a plan view of arrangements of first electrodes disposed on a first substrate shown in FIG. 1;

FIG. 3 is a cross-sectional view taken along the line III-III′ of FIG. 2;

FIG. 4 is a plan view of arrangements of second electrodes disposed on a second substrate shown in FIG. 1;

FIG. 5 is a cross-sectional view taken along the line V-V′ of FIG. 4;

FIG. 6 is an enlarged view of portion VI of FIG. 1;

FIG. 7 is a cross-sectional view of a microelectronics device according to another embodiment;

FIG. 8 is a cross-sectional view of a microelectronics device according to still another embodiment;

FIG. 9 is a cross-sectional view of a microelectronics device according to still another embodiment;

FIG. 10 is a plan view of arrangements of second electrodes on a first substrate shown in FIG. 9;

FIG. 11 is a cross-sectional view taken along the line XI-XI′ of FIG. 10;

FIG. 12 is a plan view of arrangements of second electrodes disposed on a second substrate shown in FIG. 9;

FIG. 13 is a cross-sectional view taken along the line XIII-XIII′ of FIG. 12; and

FIGS. 14 to 18 are cross-sectional views of stages in a method for forming a microelectronics device according to an embodiment.

### DETAILED DESCRIPTION

Example embodiments will now be described more fully hereinafter with reference to the accompanying drawings, in which preferred embodiments of the invention are shown. Example embodiments may, however, be embodied in different forms and should not be construed as limited to the embodiments set forth herein. Rather, these embodiments are provided so that this disclosure will be thorough and complete, and will filly convey the scope of the invention to those skilled in the art. The same reference numbers indicate the same components throughout the specification. In the attached figures, the thickness of layers and regions may be exaggerated for clarity.

It will also be understood that when a layer is referred to as being “on” another layer or substrate, it can be directly on the other layer or substrate, or intervening layers may also be present. In contrast, when an element is referred to as being “directly on” another element, there are no intervening elements present.

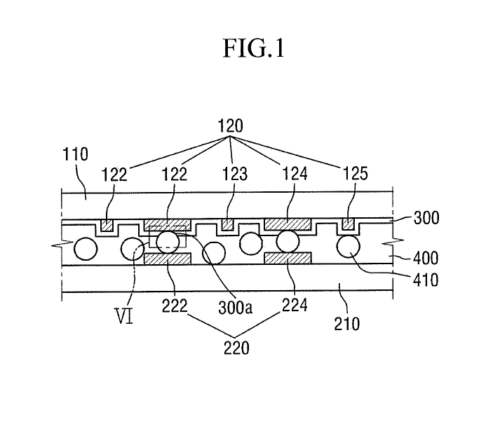

FIG. 1 is a cross-sectional view of a microelectronics device according to an embodiment.

Referring to FIG. 1, the microelectronics device according to an embodiment may include a first substrate 110, a first electrode 120 disposed on the first substrate 110, an insulating layer 300 covering the first electrode 120, an anisotropic conductive film (ACF) 400 disposed on the insulating layer 300, a second substrate 210 facing the first substrate 110 with the anisotropic conductive film 400 disposed between the first and second substrates 110 and 210, and a second electrode 220 disposed on the second substrate 210 to face the first electrode 110 while overlapping the first electrode 110.

The first substrate 110 may include various types of substrates. For example, the first substrate 110 may include a general printed circuit board (PCB), a flexible printed circuit (FPC), an integrated circuit chip, a semiconductor wafer, an insulating substrate such as glass or plastic, and so on. The first substrate 110 may include connection wires on its surface or inside. Further, the first substrate 110 may include at least one insulating layer and vias or contacts penetrating the insulating layer.

The first electrode 120 is formed on the first substrate 110. The first electrode 120 may be an electrode formed on the first substrate 110 to connect the connection wires included in the first substrate 110 to other wires in an electronic device other than the first substrate 110 or in the first substrate 110.

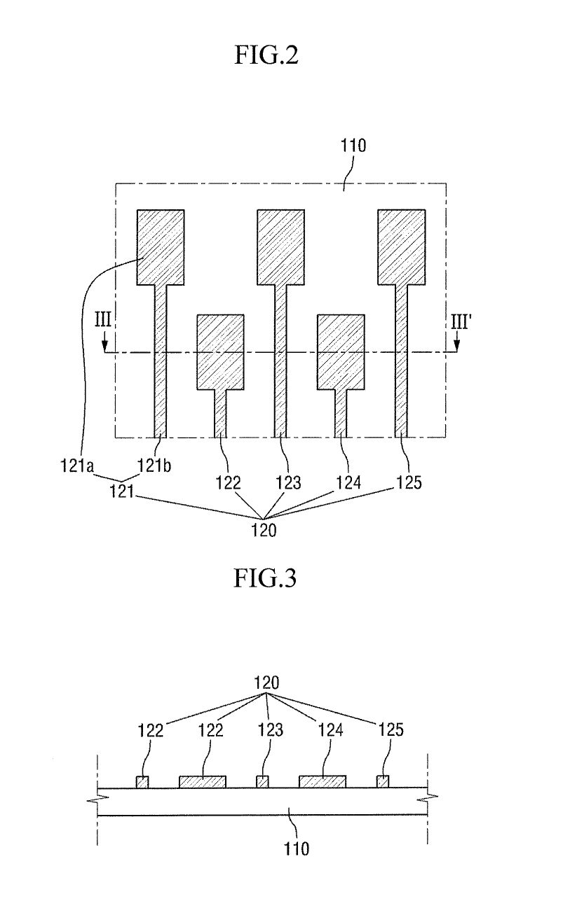

It is noted that while FIG. 1 illustrates five first electrodes 120 on the first substrate 110, the number of first electrodes 120 is not limited thereto. The first electrode 120 will be described in further detail with reference to FIGS. 2 and 3. FIG. 2 is a plan view of arrangements of the first electrodes 120 on the first substrate 110, and FIG. 3 is a cross-sectional view taken along the line III-III′ of FIG. 2.

Referring to FIGS. 2-3, at least one of the plurality of first electrodes 120 may have a first region 121a having a first width and a second region 121 b connected to the first region 121a and having a second width smaller than the first width. Here, the “width” may be measured in a direction intersecting an extending direction of a particular pattern. The first region 121a may be an extension part formed by extending the width of the second region 121b. In some embodiments, the first region 121a is formed at an end and the second region 121b extends in one direction to be connected to the connection wires. Although not shown, the first electrode 120 may include only a first region without a second region, so the first region of the first electrode 120 may be connected to the connection wires of the first substrate 110 through via holes. It is noted that while FIG. 2 illustrates the first region with a rectangular shape, example embodiments are not limited thereto, e.g., the first region may have a polygonal shape, e.g., a rhombus or a hexagon, a circular shape, etc.

The first electrodes 120 may be arranged in parallel with each other. In some embodiments, first regions 121a of adjacent first electrodes may be arranged so as not to overlap each other. For example, as shown in FIG. 2, first regions 121a of electrodes 122 and 124 may be arranged to be adjacent to second regions 121b of electrodes 121, 123, and 125. That is, a distance between each of the first regions 121a of the electrodes 122 and 124 to an adjacent second region 121b of a respective electrode 121, 123 and 125 may be smaller than a distance between each of the first regions 121a of the electrodes 122 and 124 to an adjacent first region 121a of the electrodes 121, 123 and 125. In other words, the first electrodes 120 may be arranged to have every other electrode offset along a vertical axis, i.e., an axis substantially perpendicular to a line connecting two adjacent first electrodes 120, to have the first region 121 a thereof not overlap first regions 121a of immediately adjacent first electrodes.

As such, the electrodes 121, 123, and 125 extend longer than the electrodes 122 and 124, e.g., to a further distance on the first substrate 110, so the first regions 121a of the electrodes 121, 123, and 125 may be positioned at exterior sides of terminal edges of the electrodes 122 and 124. In some embodiments, the first regions 121a of the electrodes 121, 123 and 125 may be positioned on the same line, e.g., may overlap each other. Likewise, the first regions of the electrodes 122 and 124 may be positioned on the same line, e.g., may overlap each other. However, the line on which the first regions 121a of the electrodes 122 and 124 are positioned may be different from the line on which the first regions 121a of the electrodes 121, 123 and 125 are positioned. For example, a first line connecting centers of the first regions 121a of the electrodes 122 and 124 may not overlap a second line connecting centers of the first regions 121 a of the electrodes 121, 123, and 125, so the first and second lines may define two rows of first regions 121a. In some embodiments, the first regions 121a may be arranged, such that there is no overlapping region in the two rows. In some embodiments, the first regions 121a may be arranged in three or more rows, and columns of the first regions 121a may be alternately arranged in each row.

With the illustrated configuration, as the first regions 121a having relatively large widths are not directly adjacent to each other, a distance between second regions 121 b of directly adjacent first electrodes 120 may be reduced while maintaining sufficient distance between each first region 121a of a first electrode 120 to an adjacent first electrode 120. Therefore, according to an embodiment, connection between electrodes of different substrates may be easily achieved through the relatively wide first regions 121a, while reducing a probability of occurrence of a short between adjacent electrodes due to an increased distance between the adjacent electrodes. Accordingly, a probability of interconnection failures due to the unwanted short between the electrodes may be prevented or substantially minimized.

Referring back to FIG. 1, the second substrate 210 is disposed to be spaced a predetermined distance apart from and face the first substrate 110. The second substrate 210 may include various types of substrates. For example, the second substrate 210 may include a PCB, a FPC, an integrated circuit chip, a semiconductor wafer, an insulating substrate, e.g., glass or plastic, and so on.

The second substrate 210 may be the same type as or a different type from that of the first substrate 110. The second substrate 210 may include connection wires on its surface or inside. Further, the second substrate 210 may include at least one insulating layer and vias or contacts penetrating the insulating layer.

The second electrode 220 is formed on the second substrate 210. The second electrode 120 may be an electrode formed on the second substrate 210 to connect the connection wires included in the second substrate 210 to other wires in an electronic device other than the second substrate 210 or in the second substrate 210.

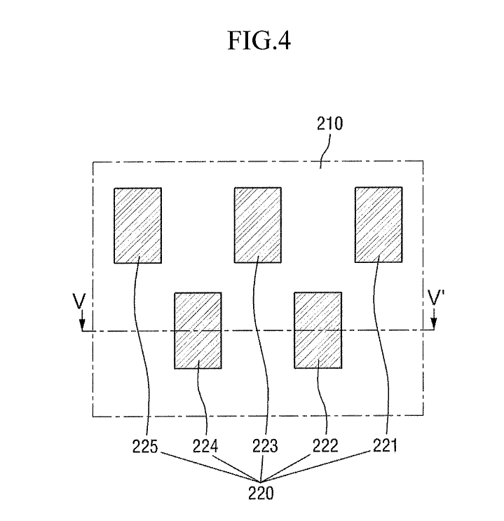

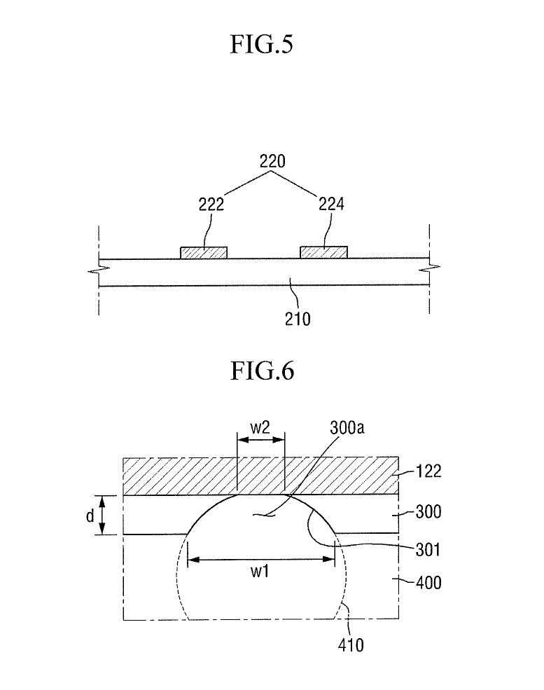

It is noted that while FIG. 1 illustrates two second electrodes 220 on the second substrate 210, the number of second electrodes is not limited thereto. The second electrodes 220 will be described in further detail with reference to FIGS. 4 and 5. FIG. 4 is a plan view of an arrangement of the second electrodes 220 on the second substrate 210, and FIG. 5 is a cross-sectional view taken along the line V-V′ of FIG. 4.

Referring to FIGS. 4 and 5, the plurality of second electrodes 220 may be connected to the connection wires of the second substrate 210 through via holes or wires covered by the insulating layer. The plurality of second electrodes 220 may be connected to the first electrodes 120, respectively. In addition to the plurality of second electrodes 220, electrodes that are not connected to the plurality of first electrodes 120 may further be arranged on the second substrate 210.

In order to electrically connect the plurality of second electrode 220 to the plurality of first electrodes 120, respectively, the plurality of second electrodes 220 and the plurality of first electrodes 120 may be arranged to face each other. For example, the plurality of second electrodes 220 and the plurality of first electrodes 120 may be arranged to overlap each other in order to be electrically connected to each other.

In some embodiments, the plurality of second electrodes 220 may be arranged to overlap first regions 121a of the plurality of first electrode 120. When the first regions 121a of the first electrodes 120 are alternately arranged, as illustrated in FIG. 2, the second electrodes 220 may also be alternately arranged, e.g., the second electrodes 220 may be positioned only above respective first regions 121a of first electrodes 120. For example, when the first regions 121a of the first electrodes 120 are arranged in two rows and columns of the first regions are alternately arranged for each row, the plurality of second electrodes 220 may also be arranged in two rows and columns of the second electrodes 220 may be alternately arranged for each row.

In some embodiments, shapes of the plurality of second electrodes 220 may be substantially the same as those of the overlapping first regions 121a. For example, if the first regions of the first electrodes 120 are rectangular, the second electrodes 220 overlapping the first regions 121a of the first electrodes 120 may also be rectangular. If the first regions 121a of the first electrodes 120 are circular, the second electrodes 220 overlapping the first regions 121a of the first electrodes 120 may also be circular. The shapes of the plurality of second electrodes 220 may be substantially the same as those of the first regions 121a. The second electrodes 220 may have any suitable size relative to the first regions 121a, i.e., larger, smaller, or the same.

Referring back to FIG. 1, the insulating layer 300 may be formed on the first substrate 110 and the first electrodes 120 to cover the plurality of first electrodes 120. According to an embodiment, as shown in FIG. 1, the insulating layer 300 may be formed into one body to entirely, e.g., and continuously, cover the plurality of first electrodes 120. Accordingly, a process of forming the insulating layer 300 may be simplified by forming the insulating layer 300 into one body, e.g., a single continuous layer covering simultaneously all the first electrodes 120.

The insulating layer 300 may be made of a general insulating material. For example, the insulating layer 300 may be made of a material that can be ruptured by an external pressure. For example, the insulating layer 300 may include an opening 300a penetrating therethrough, e.g., an opening formed by an external pressure applied to the insulating layer 300 by conductive particles to be described below. In some embodiments, the opening may be formed in a region of the insulating layer overlapping at least one of the first electrodes 120, e.g., the opening may be formed in an overlapping region of the first electrode 120 and the second electrode 220. The insulating layer 300 will be described in more detail below with reference to FIG. 6.

Referring back to FIG. 1, the ACF 400 is disposed between the insulating layer 300 and the second substrate 210. The ACF 400 may include a matrix including resin and a plurality of conductive particles 410 dispersed in the matrix. The matrix may include a thermally curable resin or a thermoplastic resin. In some embodiments, the matrix may be melted by heat or hardened by ultraviolet light. The matrix 400 may mechanically, e.g., physically, connect the first substrate 110 to the second substrate 210 via the conductive particles 410, e.g., the conductive particles 410 may be fixedly arranged to connect the first and second substrates 110 and 210.

In detail, the plurality of conductive particles 410 is made of a conductive material. For example, the plurality of conductive particles 410 may be configured such that Ni and Au are sequentially coated on a surface of polystyrene beads. However, aspects of example embodiments are not limited thereto. In some embodiments, the conductive particles 410 may have various shapes, e.g., a spherical or a substantially spherical shape.

The plurality of conductive particles 410 may apply pressure to the insulating layer 300 to form the opening therein. The conductive particles 410 are electrically connected to the first electrode 120 through the opening. For example, as illustrated in FIG. 1, the conductive particles 410 disposed in a region between a second-first electrode 122 and a second-second electrode 222 may be electrically connected to the second-first electrode 122 through the opening in the insulation layer 300, and the conductive particles 410 disposed in a region between a fourth-first electrode 144 and a fourth-second electrode 224 may be electrically connected to the fourth-first electrode 144 through the opening in the insulation layer 300. In some embodiments, the conductive particles 410 and the first electrode 120 make contact with each other to be electrically connected to each other. In addition, since the matrix of the ACF 400 includes a material capable of transmitting current from a close distance, only if the conductive particles 410 and the first electrode 120 are adjacent to each other (even if they are not necessarily in direct contact with each other), the conductive particles 410 may be electrically connected to the first electrode 120 through the opening.

The pressure applied to the insulating layer 300 from the plurality of conductive particles 410 may be pressure transmitted to the conductive particles 410 in the course of compressing the second substrate 210 with the first substrate 110. The conductive particles 410 disposed in an overlapping region of the first electrode 120 and the second electrode 220 transmit pressure to the insulating layer 300 during compression of the first and second substrates 110 and 210, thereby forming the opening in the insulating layer 300 at the overlapping region between the first and second electrodes 120 and 220. When the pressure is applied to compress the first substrate 110 with the second substrate 210, distances between the plurality of first electrodes 120 and the plurality of second electrodes 220 can be maintained constant, e.g., to equal a diameter of a conductive particle 410, by the conductive particles 410 disposed in overlapping regions of the plurality of first electrodes 120 and the plurality of second electrodes 220.

The conductive particles 410 disposed in non-overlapping regions of the plurality of first electrodes 120 and the plurality of second electrodes 220 are arranged in a region where the distance between the first substrate 110 and the second substrate 210 is greater than a width of each of the conductive particles 410. Therefore, even if pressure is applied to the first substrate 110 and the second substrate 210, the conductive particles 410 disposed in non-overlapping regions of the plurality of the first and second electrodes 120 and 220 may be subjected to smaller pressure than the particles 410 in the overlapping regions of the plurality of first and second electrodes 120 and 220. Therefore, it may not be possible to form the opening in the insulating layer 300 in regions where the first and second electrodes 120 and 220 do not overlap.

The conductive particles 410 disposed in the overlapping regions of the plurality of first electrodes 120 and the plurality of second electrodes 220 are electrically connected to the second electrode 220. For example, the conductive particles 410 disposed in a region between the second-first electrode 122 and the second-second electrode 222 may be electrically connected to the second-second electrode 222, and the conductive particles 410 disposed in a region between the fourth-first electrode 144 and the fourth-second electrode 224 may be electrically connected to the fourth-second electrode 224. In some embodiments, the conductive particles 410 and the second electrode 220 contact each other to electrically connect to each other. In addition, since the matrix includes a material capable of transmitting current from a close distance, if the conductive particles 410 and the second electrode 220 are close to each other (even if they are not necessarily in direct contact with each other), the conductive particles 410 may be electrically connected to the second electrode 220.

Among the plurality of first electrodes 120 and the plurality of second electrodes 220, overlapping electrodes are connected to the conductive particles 410 disposed in overlapping regions therebetween. Therefore, the plurality of first and second electrodes 120 and 220 are electrically connected to each other. That is, according to an embodiment, the opening is formed in the insulating layer 300 by the conductive particles 410 in the overlapping regions of the plurality of first electrodes 120 and the plurality of second electrodes 220, so that the plurality of first electrodes 120 and the plurality of second electrodes 220 may be electrically connected to each other. Meanwhile, the opening is not formed in the insulating layer 300 in the non-overlapping regions of the plurality of first electrodes 120 and the plurality of second electrodes 220, so that the electrodes positioned in the non-overlapping regions are insulated from each other.

In more detail, for example, the overlapping second-first electrode 122 and the second-second electrode 222 are electrically connected to each other. However, since no opening is formed in the first-first electrode 121 and the third-first electrode 123, which are adjacent to the second-first electrode 122 and the second-second electrode 222, the first-first electrode 121 and the third-first electrode 123 are insulated from other electrodes. Thus, the first-first electrode 121 and the third-first electrode 123 are not electrically connected to the second-first electrode 122 or the second-second electrode 222 through the conductive particles 410. Accordingly, a probability of occurrence of a short between the second-first electrode 122 or the second-second electrode 222 and an adjacent electrode, e.g., between the first-first electrode 121 and the third-first electrode 123, may be reduced. That is, according to example embodiments, a probability of occurrence of an unwanted short between adjacent electrodes can be reduced. Here, the description is based on cross-sections of overlapping regions of the second-first electrode 122 and the second-second electrode 221 and the fourth-first electrode 124 and the fourth-second electrode 224. In view of cross-sections of overlapping regions of the first-first electrode 121 and the first-second electrode 221, the third-first electrode 123 and the third-second electrode 223, and the fifth-first electrode 125 and the fifth-second electrode 225, openings may be formed in the insulating layer 400 covering the first-first electrode 121, the third-first electrode 123, and the fifth-first electrode 125.

According to an embodiment, since an unwanted short between electrodes can be prevented, a probability of the unwanted short between the electrodes can be maintained to be under a predetermined tolerance level even if a distance between interconnections is further reduced. Therefore, the electrode density can be increased and a large amount of data can be transmitted through electrodes disposed on the same area of a substrate, as compared to the conventional case.

The insulating layer 300 will be described in more detail below with reference to FIG. 6. FIG. 6 is an enlarged view of the insulating layer 300 indicated by a portion VI in FIG. 1.

Referring to FIG. 6, the insulating layer 300 includes openings 300a formed by the conductive particles 410. In some embodiments, the openings 300a may be formed such that the insulating layer 300 is ruptured by a pressure applied from the conductive particles 410 to the insulating layer 300. Therefore, sidewalls 301 of the openings may be shaped to correspond to shapes of the conductive particles 410. For example, if the conductive particles 410 are spherical, the sidewalls 301 may have arc-shaped cross sections. If the conductive particles 410 are substantially spherical, the sidewalls 301 may have curved cross sections. In some embodiments, when the conductive particles 410 are disposed in the openings, the sidewalls 301 of the openings of the insulating layer 300 and the conductive particles 410 may perfectly contact each other.

In some embodiments, the opening 300a may be formed while the conductive particle 410 penetrates the insulating layer. Therefore, the conductive particle 410 may form a hole for the opening in a first surface of the insulating layer 300, i.e., a surface facing the second substrate 210, and may penetrate through the insulating layer 300 to form a hole in a second surface of the insulating layer 300, i.e., a surface facing the first substrate 210. A width w2 of the hole in the surface facing the first substrate 110 may be equal to or smaller than a width w1 of the hole in the surface facing the second substrate 210.

In some embodiments, a thickness d of the insulating layer 300 may be equal to or smaller than a width of the conductive particle 410. If the conductive particles 410 are not spherical, the thickness d of the insulating layer may be equal to or smaller than a minimum width of the conductive particle 410. If the thickness d of the insulating layer 300 is equal to or smaller than the minimum width of the conductive particle 410, the conductive particles 410 dispersed in the opening may contact the first electrode 120 and the second electrode 220 at the same time, thereby electrically connect the first electrode 120 and the second electrode 220 to each other.

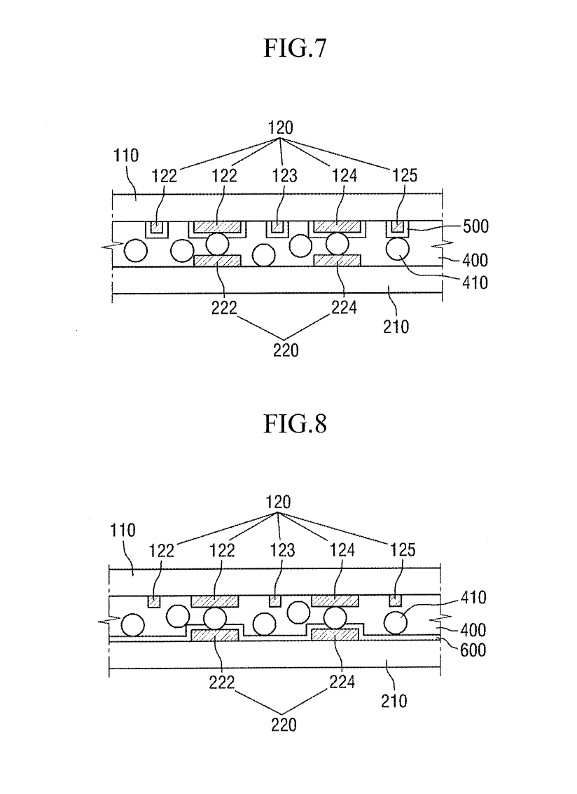

FIG. 7 is a cross-sectional view of a microelectronics device according to another embodiment.

Referring to FIG. 7, the microelectronics device includes the first substrate 110, the first electrode 120 disposed on the first substrate 110, an insulating layer 500 covering the first electrode 120, the ACF 400 disposed on the insulating layer 500, the second substrate 210 facing the first substrate 110 with the ACF 400 disposed between the first and second substrates 110 and 210, and the second electrode 220 disposed on the second substrate 210 to face and overlap the first electrode 110.

The insulating layer 500 may be disposed to cover a plurality of first electrodes 120 on one surface of the first substrate 110 facing the second substrate 210. The insulating layer 500 may not be formed into one body but may be divided to be disposed in regions in which the plurality of first electrodes 120 can be covered. For example, the insulating layer 500 may include a plurality of discrete, e.g., discontinuous, portions, such that each discrete portion may be positioned on a respective first electrode 120. Since the insulating layer 500 is disposed only in the regions required to cover the plurality of first electrodes 120, e.g., no separate portions of the insulating layer 500 may be positioned between adjacent first electrodes 120, consumption of raw materials necessary for forming the insulating layer is reduced, thereby reducing manufacturing costs, as compared to a an insulating layer formed as one body. Even if the insulating layer 500 is divided to be disposed in the regions in which the plurality of first electrodes 120 can be covered, openings may not be formed in the insulating layer 500 of non-overlapping regions of the plurality of first electrodes 120 and the plurality of second electrodes 220 by a pressure applied from the conductive particles 410 to the insulating layer 500, thereby preventing a unwanted short of electrodes.

FIG. 8 is a cross-sectional view of a microelectronics device according to still another embodiment.

Referring to FIG. 8, the microelectronics device may include the first substrate 110, the first electrode 120 disposed on the first substrate 110, the second substrate 210 spaced apart from and facing the first substrate 110, the second electrode 220 disposed on the second substrate 210 to face and overlap the first electrode 120, an insulating layer 600 covering the second electrode 220, and the ACF 400 disposed between each of the insulating layer 600 and the first substrate 110.

The insulating layer 600 may be formed on a surface of the second substrate 210 facing the first substrate 110. The insulating layer 600 may be formed to continuously cover the plurality of second electrodes 220. If the insulating layer 600 is formed into one body, the manufacturing process can be simplified. In addition, in some embodiments, although not shown, the insulating layer 600 may not be formed into one body but may be divided to be disposed in regions in which the plurality of first electrodes 120 can be covered. If the insulating layer 600 is divided to be disposed, consumption of raw materials necessary for forming the insulating layer is reduced, thereby reducing the cost.

The plurality of second electrodes 220 are electrically connected to the conductive particles 410 disposed in openings through the insulating layer 600. The conductive particles 410 disposed in the openings are electrically connected to the first electrode 120, thereby allowing the overlapping plurality of first electrodes 120 and the plurality of second electrodes 220 to be electrically connected to each other. For example, the conductive particles dispersed between the second-first electrode 122 and the second-second electrode 222 are connected to the second-second electrode 222 through the openings while contacting or being close to the second-first electrode 122, thereby establishing electrical connection. Thus, the conductive particles 410 dispersed between the second-first electrode 122 and the second-second electrode 222 may electrically connect the second-first electrode 122 and the second-second electrode 222 to each other.

A probability of occurrence of shorts among the overlapping plurality of second electrodes 220, which are adjacent to the plurality of first electrodes 120, is reduced. For example, the second-second electrode 222 and the second-first electrode 122 overlap each other. The second-first electrode 122 is adjacent to the first-first electrode 121 and the third-first electrode 123. The openings are formed in the insulating layer 600 by the pressure applied from the conductive particles 410 to sidewalls of the second-second electrode 222 and the conductive particles 410 are disposed in the openings. Therefore, shorts may occur between the first-first electrode 121 or the third-first electrode 123 and the second-second electrode 222. However, since a sufficient pressure to form the openings in the insulating layer 600 is not applied from the conductive particles 410 to the sidewalls of the second-second electrode 222, a probability of occurrence of a short between the second-second electrode 222 and the first-first electrodes 121 or the third-first electrode 123 is reduced. That is to say, in some embodiments, a probability of occurrence of shorts between the plurality of second electrodes 220 and first electrodes adjacent to the overlapping plurality of first electrodes 120 is reduced.

Although not shown, in some embodiments, the microelectronics device may be formed to include both the insulating layer 300 formed on the first substrate 110, as shown in FIG. 5, and the insulating layer 600 formed on the second substrate 210, as shown in FIG. 8.

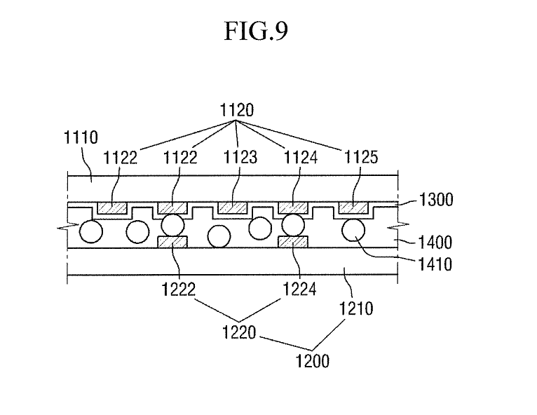

FIG. 9 is a cross-sectional view of a microelectronics device according to still another embodiment.

Referring to FIG. 9, the microelectronics device may include a first substrate 1110, a first electrode 1120 disposed on the first substrate 1110, an insulating layer 1300 covering the first electrode 1120, an ACF 400 disposed on the insulating layer 1300, a second substrate 1210 facing the first substrate 1110 with the ACF 400 interposed between the first and second substrates 1110 and 1210, and a second electrode 1220 disposed on the second substrate 1210 to face and overlap the first electrode 1120. For example, a plurality of first electrodes 1120 may be arranged on the first substrate 1110.

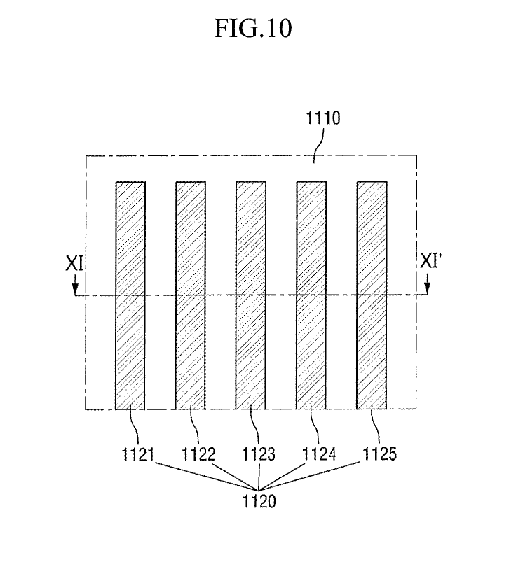

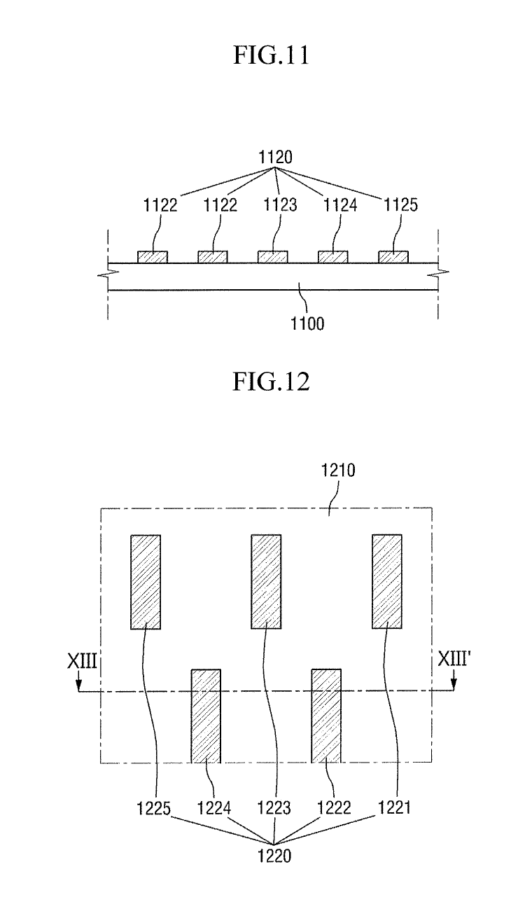

The first electrode will further be described in detail with reference to FIGS. 10 and 11. FIG. 10 is a plan view illustrating arrangements of second electrodes disposed on a first substrate shown in FIG. 9, and FIG. 11 is a cross-sectional view taken along the line XI-XI′ of FIG. 10.

Referring to FIGS. 10 and 11, each of the plurality of first electrodes 1120 may have a predetermined width. If the widths of the plurality of first electrodes 1120 are substantially constant, the electrode manufacturing process can be simplified and facilitated.

Referring back to FIG. 9, the second electrode 1220 is formed on the second substrate 1210. The second electrode 1220 may be an electrode formed on the second substrate 1210 to connect connection wires included in the second substrate 1210 to other wires in an electronic device other than the second substrate 1210 or in the second substrate 1210.

In some embodiments, a plurality of second electrodes 1220 may be electrodes that can be connected to a plurality of first electrodes 1120 formed on the first substrate 1110, and the second substrate 1210 may further include electrodes that are not connected to the first electrodes 1120 in addition to the plurality of second electrodes 1220.

The second electrode will further be described in detail with reference to FIGS.

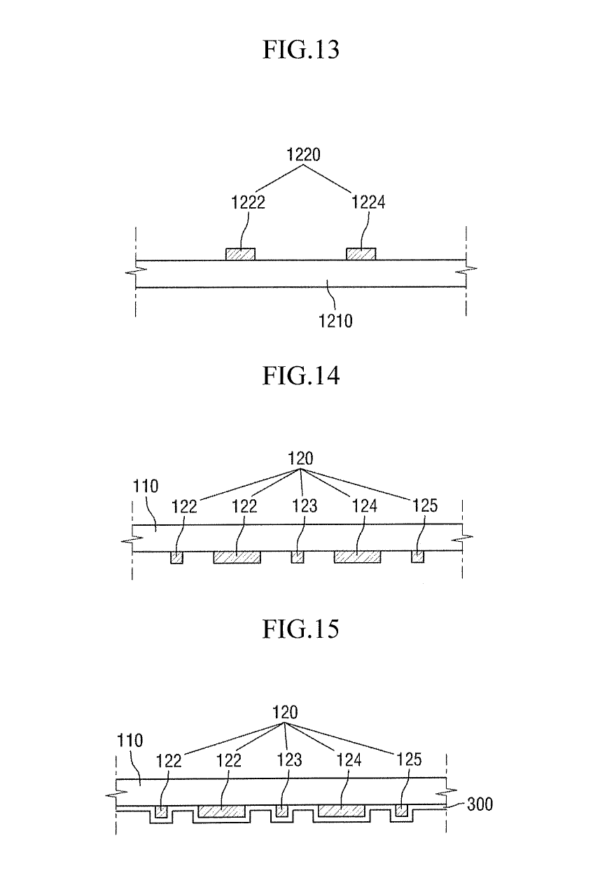

12 and 13. FIG. 12 is a plan view illustrating arrangements of second electrodes disposed on a second substrate shown in FIG. 9, and FIG. 13 is a cross-sectional view taken along the line XIII-XIII′ of FIG. 12.

In order to electrically connect the plurality of second electrodes 1220 to the plurality of first electrodes 1120, the first substrate 1110 and the second substrate 1210 may be disposed such that the plurality of second electrodes 1220 and the plurality of first electrodes 1120 with the ACF 400 interposed therebetween. Thus, the plurality of second electrodes 1220 and the plurality of first electrodes 1120 may be disposed to overlap each other in at least some regions.

The plurality of second electrodes 1220 may be formed to overlap only some regions of the plurality of first electrodes 1120. For example, as shown in FIG. 12, the plurality of second electrodes 1220 are arranged in two rows, and columns of the plurality of second electrodes 1220 may be alternately arranged for each row. In some embodiments, the plurality of second electrodes 1220 may also be arranged such that the two rows may not overlap each other in any region. Although not shown, in some embodiments, the plurality of second electrodes 1220 may also be arranged in three or more rows, and columns of the second electrodes 1220 may be alternately arranged in each row.

With the illustrated configuration, the overlapping region of the first electrode 1120 and the second electrode 1220 may be disposed so as not to be adjacent to each other in a horizontal direction and a relatively large horizontal distance can be obtained in the overlapping region of the first electrode 1120 and the second electrode 1220. In some embodiments, which will be described later, as openings are formed in the insulating layer 1300 only in the overlapping region of the first electrode 1120 and the second electrode 1220, it is possible to reduce a probability of occurrence of an unwanted short between adjacent electrodes.

Referring back to FIG. 9, the insulating layer 1300 is formed on a surface of the first substrate 1110 facing the second substrate 1210. The insulating layer 1300 may be formed to cover a plurality of first electrode 1120. Accordingly, a process of forming the insulating layer 1300 can be simplified by forming the insulating layer 1300 into one body.

Although not shown, the insulating layer 1300 may not be formed into one body but may be divided to be disposed in regions in which the plurality of first electrodes 1120 can be covered. If the insulating layer 1300 is divided into a plurality of portions, consumption of raw materials necessary for forming the insulating layer is reduced, thereby reducing the cost.

The conductive particles 1410 disposed in the overlapping region of the first electrode 1120 and the second electrode 1220 may form openings in the insulating layer 1300 formed on the first electrode 1120. In some embodiments, the conductive particles 410 may form the openings in the insulating layer 1300 in the overlapping region of the first electrode 1120 and the second electrode 1220. The conductive particles 1410 forming the openings may be electrically connected to the first electrode 1120 through the openings.

Since the conductive particles 410 disposed in the non-overlapping region of the first electrode 1120 and the second electrode 1220 is not subjected to a sufficiently large pressure, the openings may not be formed in the insulating layer 1300. That is to say, as shown in FIG. 9, openings are not formed in the insulating layer 1300 covering a first-first electrode 1121, a third-first electrode 1123, or a fifth-first electrode 1125, so as to be insulated from other adjacent electrodes. Therefore, a probability of occurrence of a short between the second-first electrode 1122 having openings in the insulating layer 1300 formed thereon and the first-first electrode 1121 or the third-first electrode 1123 is reduced. That is, a probability of occurrence of a short between the first electrodes 1120 adjacent to each other is reduced. Here, the description is based on cross-sections of overlapping regions of the second-first electrode 1122 and the second-second electrode 1222 and the fourth-first electrode 1124 and the fourth-second electrode 1224. In view of cross-sections of overlapping regions of the first-first electrode 1121 and the first-second electrode 1221, the third-first electrode 1123 and the third-second electrode 1223, and the fifth-first electrode 1125 and the fifth-second electrode 1225, openings may be formed in the insulating layer 1300 covering the first-first electrode 1121, the third-first electrode 1123 and the fifth-first electrode 1125.

For example, the second-second electrode 1222 is adjacent to the first-first electrode 1121 and the third-first electrode 1123, except for the second-second electrode 1122 electrically connected to second-second electrode 1122. As described above, as openings are not formed in the insulating layer 1300 on the first-first electrode 1121 and the third-first electrode 1123, the first-first electrode 1121 and the third-first electrode 1123 are electrically insulated from other electrodes. Therefore, a probability of occurrence of a short between the second-second electrode 1222 and the first-first electrode 1121 or the third-first electrode 1123 is reduced. That is, it is possible to reduce a probability of occurrence of shorts between the plurality of second electrodes 1220 and the first electrodes 1120 among the plurality of first electrodes 1120 intended to be electrically connected to the plurality of second electrode 1220.

Hereinafter, a method for forming a microelectronics device according to an embodiment will be described with reference to FIGS. 14 to 18. FIGS. 14 to 18 are cross-sectional views of stages in a method for forming a microelectronics device according to an embodiment of the example embodiments.

Referring to FIG. 14, forming the microelectronics device according to an embodiment includes preparing the first substrate 110 and the plurality of first electrodes 120 formed on the first substrate 110.

Referring to FIG. 15, the insulating layer 300 is formed to cover the plurality of first electrodes 120 on a surface of the first substrate 110 having the plurality of first electrodes 120 disposed thereon. The insulating layer 300 may be formed by a screen method using a mask. Although FIG. 15 illustrates that the insulating layer 300 is formed as one body, the insulating layer, e.g., the insulating layer 500 of FIG. 7, may be divided into a plurality of portions to cover the first electrodes 120 separately from each other.

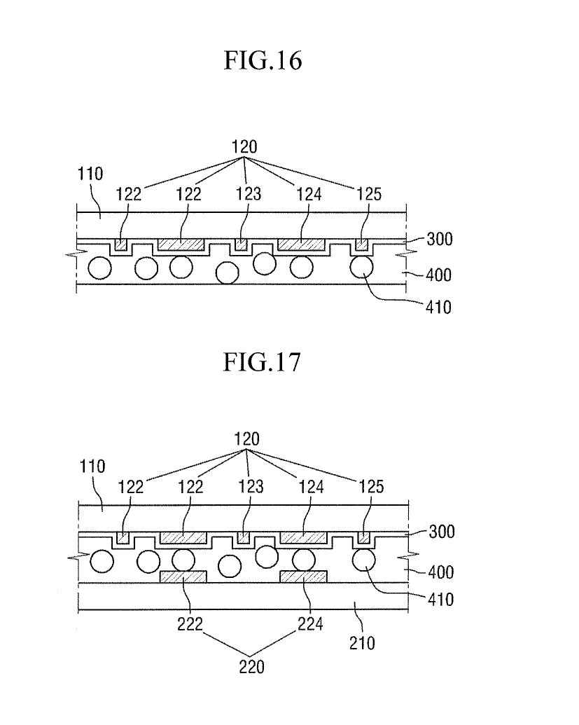

Referring to FIG. 16, the ACF 400 including a matrix and a plurality of conductive particles 410 dispersed in the matrix may be formed on the insulating layer 300. The ACF 400 may be formed by providing an anisotropic conductive layer on the insulating layer 300. In some embodiments, the anisotropic conductive layer generally includes an anisotropic conductive film and a film adhered to the anisotropic conductive film. The anisotropic conductive layer is disposed such that the matrix is adjacent to the insulating layer and the film is then removed, thereby forming the ACF 400 on the insulating layer 300, as shown in FIG. 16.

Referring to FIG. 17, the second substrate 210 is disposed on the other surface of the ACF 400, on which the first substrate 110 is disposed. The plurality of second electrodes 220 are formed on the second substrate 210, and the second substrate 210 and the plurality of second electrodes 220 may be arranged such that the plurality of second electrodes 220 face the first substrate 110. In some embodiments, the second substrate 210 may be arranged such that the plurality of second electrodes 220 and the plurality of first electrodes 120 overlap each other in as many regions as possible.

As shown in FIG. 17, after the second substrate 210 is arranged, if pressure is applied to the first substrate 110 and the second substrate 210 in opposite directions, openings are formed in the insulating layer 300 by the conductive particles 410 disposed in overlapping regions of the first electrodes 120 and the second electrodes 220, thereby forming the microelectronics device shown in FIG. 1.

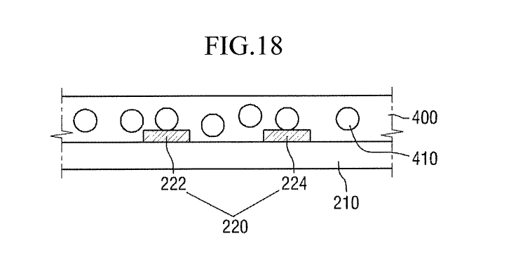

Alternatively, instead the stage illustrated in FIG. 15, the second substrate 210 is prepared, and the ACF 400 may be formed on a surface of the second substrate 210, on which the second electrodes 220 are formed, as illustrated in FIG. 18. Thereafter, the insulating layer 300 covering the first substrate 110 and the first electrodes 120, as shown in FIG. 14, may be disposed on the other surface of the ACF 400, on which the second substrate 210 is disposed. The second substrate 210 may be configured, as shown in FIG. 17, such that the plurality of second electrodes 220 face the first substrate 110. In addition, if the pressure is applied to the first substrate 110 and the second substrate 210 in opposite directions, the openings are formed in the insulating layer 300 by the conductive particles 410, thereby forming the microelectronics device shown in FIG. 1.

While the example embodiments has been particularly shown and described with reference to exemplary embodiments thereof, it will be understood by those of ordinary skill in the art that various changes in form and details may be made therein without departing from the spirit and scope of the example embodiments as defined by the following claims. It is therefore desired that the present embodiments be considered in all respects as illustrative and not restrictive, reference being made to the appended claims rather than the foregoing description to indicate the scope of the invention.

What is claimed is:

1. A microelectronics device, comprising:
a first substrate;
first electrodes disposed on the first substrate;
an insulating layer covering the first electrodes, the insulating layer including openings on the first electrodes; and
an anisotropic conductive film on the insulating layer, the anisotropic conductive film including conductive particles electrically connected to the first electrodes through the openings.

2. The microelectronics device of claim 1, wherein the opening includes a sidewall having a shape corresponding to the conductive particle.

3. The microelectronics device of claim 1, wherein the opening includes a sidewall having a curved cross-section.

4. The microelectronics device of claim 3, wherein the sidewall of the opening has an arc-shaped cross-section.

5. The microelectronics device of claim 1, wherein the first electrodes and the conductive particles contact each other through the openings.

6. The microelectronics device of claim 1, wherein a width of a surface of the opening facing the first electrode is equal to or less than a width of a surface of the opening facing the anisotropic conductive film.

7. The microelectronics device of claim 1, further comprising:
a second substrate facing the first substrate, the anisotropic conductive film being disposed between the first and second substrates; and
second electrodes on the second substrate, the second electrodes facing and overlapping the first electrodes, and the second electrodes and the conductive particles being electrically connected to each other.

8. The microelectronics device of claim 1, wherein a thickness of the insulating layer is equal to or less than a minimum width of the conductive particle.

9. The microelectronics device of claim 1, wherein the conductive particles are on the first electrodes, each of the first electrodes being electrically connected to a respective conductive particle disposed thereon.

10. The microelectronics device of claim 9, wherein each first electrode is electrically connected to the conductive particle thereon through the opening.

11. The microelectronics device of claim 9, wherein each first electrode completely overlaps a respective opening, such that there are no openings between adjacent first electrodes.

12. The microelectronics device of claim 9, wherein the insulating layer is a single layer overlapping simultaneously all of the first electrodes.

13. The microelectronics device of claim 9, further comprising:
a second substrate facing the first substrate with the anisotropic conductive film disposed between the first and second substrates; and
second electrodes on the second substrate, the second electrodes facing and overlapping the first electrodes, the second electrodes and the conductive particles being electrically connected to each other, and the conductive particles disposed on overlapping areas of the first electrodes and second electrodes being electrically connected to the second electrodes, respectively.

14. The microelectronics device of claim 13, wherein each of the first electrodes has a first region and a second region, the second region having a smaller width than the first region.

15. The microelectronics device of claim 14, wherein the second electrodes overlap the first regions of the first electrodes.

16. The microelectronics device of claim 14, wherein a minimum distance between adjacent ones of the first electrodes is a distance between the first region of one of the first electrodes and the second region of the first electrode adjacent to the one first electrode.

17. The microelectronics device of claim 13, wherein the second electrodes are arranged in a plurality of rows, adjacent ones of the second electrodes being in different rows of the plurality of rows.

18. A method of forming a microelectronics device, the method comprising:
forming first electrodes on a first substrate;
forming an insulating layer covering the first electrodes;
providing an anisotropic conductive film on the insulating layer, the anisotropic conductive film including conductive particles dispersed in a matrix;
forming second electrodes on a second substrate;
arranging the second substrate with the second electrodes on the anisotropic conductive film, such that the first electrodes and the second electrodes overlap each other; and
compressing the first substrate and the second substrate, such that the first and second electrodes compress against each other with the anisotropic conductive film therebetween.

19. The method of claim 18, wherein compressing the first and second substrates includes forming openings in the insulating layer by the conductive particles, such that the conductive particles are electrically connected to the first electrodes.

20. The method of claim 19, wherein the openings are formed only in regions overlapping the first and second electrodes, such that regions between adjacent first electrodes or regions between adjacent second electrodes include no openings.
